(19) United States
(12) Patent Application Publication
(10) Pub. No.: US 2013/0221383 A1
(43) Pub. Date: Aug. 29, 2013

(54) TRANSPARENT LIGHT EMITTING DIODE PACKAGE AND FABRICATION METHOD THEROF

(71) Applicant: SAMSUNG ELECTRONICS CO., LTD., (US)

(72) Inventors: Soo Jeong LEE, Daejeon (KR); Hyung Kun KIM, Suwon-si (KR)

(73) Assignee: SAMSUNG ELECTRONICS CO., LTD., Suwon-si (KR)

(21) Appl. No.: 13/777,962

(22) Filed: Feb. 26, 2013

(30) Foreign Application Priority Data
Feb. 27, 2012 (KR) 10-2012-0019651

(51) Int. Cl. H01L 33/60; H01L 33/08

(52) U.S. Cl. CPC H01L 33/60; H01L 33/08; Y10S 977/762; Y10S 977/95; B82Y 20/00
USPC 257/88; 257/98; 977/950; 977/762

(57) ABSTRACT

A light emitting diode (LED) package and a method of fabricating an LED package are provided. The LED package can include a transparent substrate and an LED arranged on the transparent substrate. A reflective layer and/or a polarizing layer can also be included. The LED may be disposed on one surface of the transparent substrate with the reflective layer and/or polarizing layer formed on an opposing surface of the transparent substrate. The fabrication method may include forming an LED on one surface of a transparent substrate by mounting a flip-chip on the transparent substrate or vapor-depositing the LED directly on the transparent substrate. A multi-package stacked structure can also be provided wherein a plurality of LED packages are stacked together unidirectionally or bidirectionally, with or without a reflective layer and/or a polarizing layer.

### CROSS-REFERENCE TO RELATED APPLICATION

This application claims the benefit of Korean Patent Application No. 10-2012-0019651, filed on Feb. 27, 2012, in the Korean Intellectual Property Office, the disclosure of which is incorporated herein by reference in its entirety.

### BACKGROUND

1. Technical Field

The present inventive concepts relate to a light emitting diode (LED) package and a method of fabricating the LED package, and more particularly, to an LED package including a transparent substrate, a reflective layer, a polarizing layer, and the like, and a method of fabricating the same.

2. Description of the Related Art

A light emitting diode (LED) refers to a semiconductor that emits light when a current flows through it. Due to long its lifespan, low power consumption, high response rate, excellent initial driving characteristics, and other beneficial characteristics, LEDs are being widely used in various fields, including lighting apparatuses, electric signs, back light units for display devices, and the like. Furthermore, the number of areas in which LED technology can be applied is expanding.

Recently, LEDs have been used as light sources in various colors. With an increased demand for a high output and high radiation intensity LED, research is being actively conducted to increase the performance and reliability of LED packages. To increase the performance characteristics of an LED product, LEDs having a high luminous efficiency as well, LED packages which efficiently extract light, and which have high color purity and uniform characteristics are desirable.

FIG. 1 is a schematic view of a general LED package 100 according to the related art. Even with the excellent optical characteristics of LEDs, since a substrate 110 of the LED package 100 is conventionally made of an opaque material, the LED package 100 may reduce the luminous efficiency by partially absorbing light generated from the LED 120. In addition, the light emitted from the LED 120 may be partially lost through being absorbed by materials of the LED package, such as materials for an encapsulant, the substrate 110, a lead frame, a metal line 130 used for wire bonding, and the like.

### SUMMARY

According to one aspect of the present inventive concepts, a light emitting diode (LED) package is provided which is capable of achieving high radiation intensity by reducing light intensity lost by package materials. A fabrication method for the LED package is also provided. In particular, a method of increasing luminous efficiency of the LED package can be realized by employing a transparent substrate, forming a reflective layer and a polarizing layer, and depositing the LED package in various configurations.

According to an aspect of the present inventive concepts, a light emitting diode (LED) package can include a transparent substrate which comprises at least one material selected from a group consisting of indium tin oxide (ITO), a carbon nanotube (CNT), tin oxide (SnO₂), zinc oxide (ZnO), glass, a conductive polymer, poly(3,4-ethylene dioxythiophene) (PEDOT), grid electrode film (GEF), coating or mesh containing a conductive material, a compound of glass fibers and organic materials, and carbon graphene; and anAn LED can be disposed on one surface of the transparent substrate. The transparent substrate may be a flexible substrate, and the LED may be flip-chip bonded or vapor-deposited to the transparent substrate.

The LED package may further include a reflective layer disposed on the transparent substrate. The LED package may further include a polarizing layer disposed on the transparent substrate. The LED package may be provided in a stacked structure which includes at least two LED packages being stacked. The LED package may further include a reflective layer disposed between stacked LED packages. The LED package may further include a polarizing layer disposed between the stacked LED packages.

According to another aspect of the present inventive concepts, a method of fabricating an LED package can include forming an LED on one surface of a transparent substrate. Forming the LED may be performed, for instance, by mounting a flip-chip on the transparent substrate or by vapor-depositing the LED directly on the transparent substrate. The fabrication method may further include forming either or both of a polarizing layer and a reflective layer.

According to embodiments of the present inventive concepts, when the substrate is made of a transparent material, light loss in a light emitting diode (LED) package caused by the substrate absorbing the light can be substantially reduced. Furthermore, when the LED is flip-chip mounted or vapor-deposited on the substrate, light absorption and light loss caused by a metal line for wire bonding can also be avoided. In addition, the luminous efficiency of the LED package may be increased by utilizing a reflective layer and a polarizing layer.

Additionally, in an LED package fabrication method performed in accordance with aspects of the present inventive concepts, the fabrication process may be simplified by omitting wire bonding or die bonding. An amount of material wasted in an isolation process may also be reduced, thereby reducing the unit cost of production. In addition, since a pattern printing method is used, diversification of product size may be enabled at a lower cost.

### BRIEF DESCRIPTION OF THE DRAWINGS

These and/or other aspects, features, and advantages of the present inventive concepts will become apparent and more readily appreciated from the following description of exemplary embodiments, taken in conjunction with the accompanying drawings of which:

FIG. 1 is a schematic illustration of a conventional light emitting diode (LED) package according to the related art;

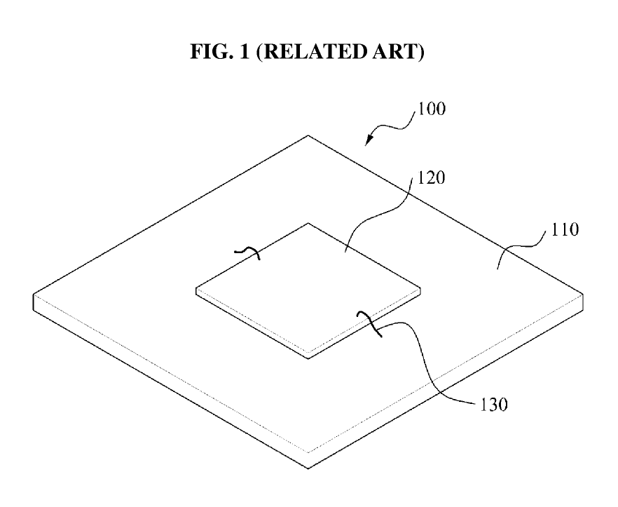

FIG. 2 is a schematic illustration of an LED package according to an embodiment of the present inventive concepts;

FIG. 3 is a schematic side view of an LED package according to one embodiment of the present inventive concepts;

FIG. 4 is a schematic side view of an LED package according to another embodiment of the present inventive concepts;

FIG. 5 is a schematic side view of an LED package according to a still further embodiment of the present inventive concepts;

FIG. 6 is a schematic perspective view of a stacked structure of LED packages, according to yet another embodiment of the present inventive concepts;

FIG. 7 is a schematic side view of a stacked structure of LED packages, according to another embodiment of the present inventive concepts;

FIG. 8 is a schematic side view of a stacked structure of LED packages, according to a further embodiment of the present inventive concepts;

FIGS. 9A and 9B are schematic side views of stacked structure LED packages, constructed according to still further embodiments of the present inventive concepts;

FIG. 10 is a schematic side view of a stacked structure of LED packages, according to yet another embodiment of the present inventive concepts; and

FIG. 11 is a flowchart illustrating various alternative LED package fabrication methods according to embodiments of the present inventive concepts.

### DETAILED DESCRIPTION

Reference will now be made in detail to exemplary embodiments of the present inventive concepts, examples of which are illustrated in the accompanying drawings, wherein like reference numerals refer to the like elements throughout. The terms used herein to describe the present inventive concepts may be defined or understood based on their functions in the present inventive concepts and may vary according to users, user's intentions, or practices. Therefore, the definitions of the terms should be determined based on the entire disclosure.

For example, in the following description, it will be understood that when a substrate, a layer, or a surface is referred to as being “on” or “under” another element, it can be directly on another element or intervening elements may be present. In addition, when an element is referred to as being “on” or “under” another element, the relative terms ‘on’ and ‘under’ are made simply on the basis of the orientation in the drawings. Such terms shall be interpreted to cover alternative orientations in addition to the orientations represented by the drawings. The sizes of each element may be exaggerated for convenience in description and such representations do not necessarily reflect the actual size of the element.

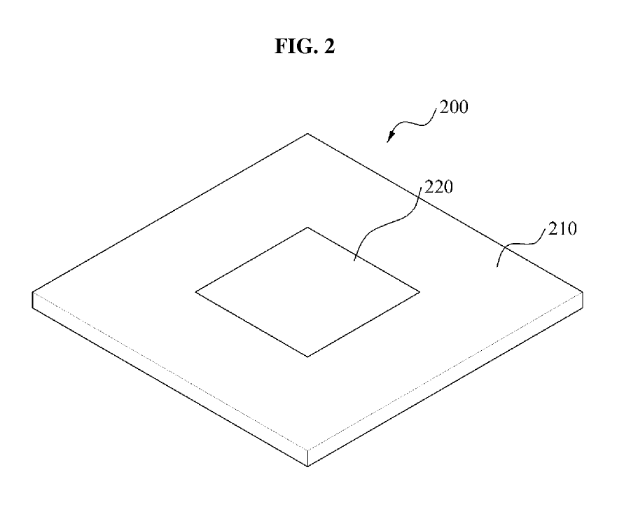

FIG. 2 schematically illustrates a light emitting diode (LED) package 200 according to an embodiment of the present inventive concepts. Referring to FIG. 2, the LED package 200 may include a transparent substrate 210, and an LED 220 disposed on one surface of the transparent substrate 210. According to the present embodiment, the transparent substrate 210 can be made of a transparent material. The transparent material may efficiently transmit the light from the LED 220 without absorbing the light, thereby preventing a loss of light attributable to light absorption.

For example, the transparent substrate 210 may include one or more materials such as indium tin oxide (ITO) and a carbon nanotube (CNT). Or the transparent substrate may be based on at least one of tin oxide (SnO₂) and zinc oxide (ZnO). In other forms, the transparent substrate may comprise a glass transparent substrate, a transparent substrate including a conductive polymer, a poly(3,4-ethylene dioxythiophene) (PEDOT)-based thin film, a grid electrode film (GEF), a transparent substrate formed by coating or mesh-printing a conductive material on a film, a transparent plastic substrate formed by mixing glass fibers and organic materials, and/or a transparent substrate including carbon graphene. The polymer transparent substrate and the transparent substrate including the carbon graphene, for example, can have high flexibility. Carbon graphene may further be a desirable material for a substrate of an LED package since it has not only flexibility, but further has a conductivity equivalent to that of a metal conductor.

In some embodiments, the transparent substrate 210 may be a flexible substrate. A substrate having both transparency and flexibility may be desirable in various fields and applications. In particular, various practical demands for a transparent and flexible substrate exist, such as in a flexible touch display panel. Accordingly, embodiments of the present inventive concepts which provide a flexible, transparent substrate may be more competitive than embodiments which lack flexibility.

The LED 220 may be bonded to the transparent substrate 210 by a wireless flip-chip method or may be directly vapor-deposited on the transparent substrate 210. Etching and evaporation processes, for example, can be performed at a wafer-level during fabrication of a semiconductor chip. Next, after performing predetermined testing procedures, packaging of the chips can be performed. During the packaging process, a chip may be mounted and molded on a substrate equipped with an external terminal. The external terminal can be a terminal that electrically connects the substrate with the chip. Methods for connecting the external terminal with the chip may, for instance, include wire bonding and flip-chip bonding.

In the case of wire bonding, the chip is disposed on the substrate equipped with an external terminal, and an electrode pattern of the chip is electrically connected to the substrate by connecting an internal terminal with the external terminal using a fine wire (typically made of metal). In the case of flip-chip bonding, protrusions (i.e., conductive bumps such as solder bomps) are formed on the chip in communication with the internal terminals of the chip (i.e., a chip pad). The protrusions are then electrically connected with the electrode pattern of the substrate. Flip-chip bonding may also be referred to as wireless bonding since wire interconnections are not necessary.

Since wire connections are unnecessary, flip-chip bonding may save space (i.e., an amount of space equivalent to a wire bonding area), and is therefore efficient for forming small packages. For example, flip-chip bonding may reduce the volume required for the chip package by about 25%. Also, a connection distance between the chip and the substrate can be minimized, and impedance may therefore be approximated to zero. Furthermore, a heat radiation path can be more evenly distributed, and heat generated inside the chip may therefore be more quickly and efficiently radiated. When the LED is bonded to the transparent substrate by flip-chip bonding, the fabrication process may also be simplified, since wire bonding is omitted. And, as discussed above, by omitting the metal wire, space efficiency may be increased. Moreover, light reflection and/or light interruption that may be caused by the metal wire can be prevented, thereby increasing the luminous efficiency.

Alternatively, the LED chip can be vapor-deposited directly on the transparent substrate, and various patterns may be printed. Screen printing and micro pattern formation methods (such as photo etching) have recently become more highly developed, and direct vapor-deposition of the LED chip on the transparent substrate is therefore possible.

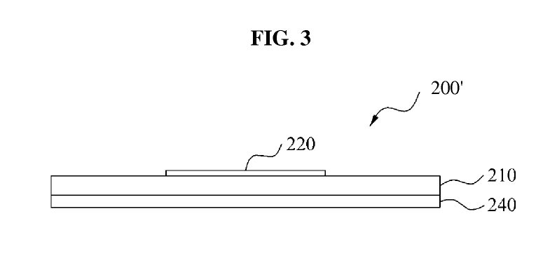

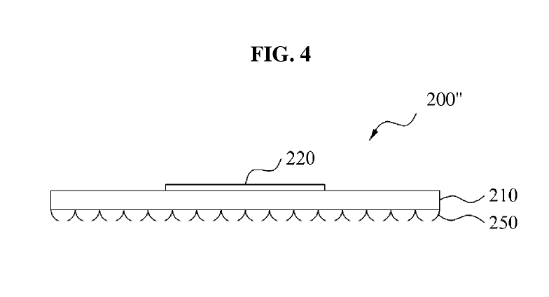

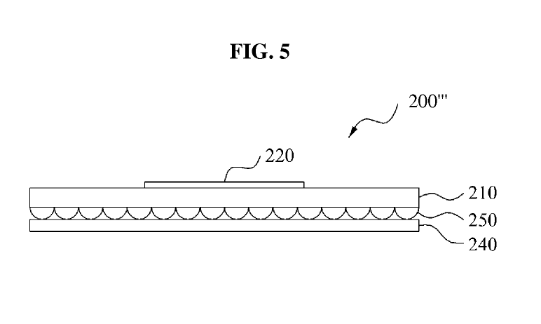

According to another embodiment of the present inventive concepts, the LED package may include a reflective layer and/or a polarizing layer disposed on a surface of the transparent substrate opposite the LED. FIG. 3 is a schematic side view of an LED package 200′ having a transparent substrate 210 and a reflective layer 240, according to one embodiment of the present inventive concepts. FIG. 4 is a schematic side view of an LED package 200″ having a transparent substrate 210 and a polarized layer 250, according to another embodiment of the present inventive concepts. FIG. 5 is a schematic side view of an LED package 200′″ having a transparent substrate 210, a polarized layer 250, and a reflective layer 240, according to a still further embodiment of the present inventive concepts.

According to various embodiments, the reflective layer may be configured to selectively reflect only a particular wavelength or range of wavelengths, based on a material of the reflective layer. The LED package can thereby be configured to reinforce that particular wavelength (or range). The polarizing layer may be configured to selectively emit light having an oscillation wavelength in a desired direction by polarizing vertical or horizontal light, for example. The luminous efficiency may be increased when either the reflective layer or the polarizing layer is provided. When both of the reflective layer and the polarizing layer are provided, the luminous efficiency can be further increased.

Referring first to FIG. 3, the LED package 200′ may include a transparent substrate 210, an LED 220, and a reflective layer 240. The transparent substrate 210 may, for example, be a glass substrate, a transparent polymer substrate, a carbon graphene substrate, or a flexible substrate. For this embodiment, the transparent polymer substrate is preferably adopted. The LED 220 can be flip-chip bonded to one surface of the transparent substrate 210.

The reflective layer 240 can be disposed on an opposite surface of the transparent substrate. Since the substrate is transparent, light generated from the LED 220 may be transmitted through the transparent substrate without being absorbed. The reflective layer may reflect the transmitted light back in a forward direction (that is, the direction from the transparent substrate to the LED), thereby increasing the luminous efficiency.

By providing a reflective layer on a surface of the transparent layer opposite the LED, the reflective layer can reflect light generated by the LED back in a forward direction that would otherwise be lost through the back side of the LED package, thereby increasing the luminous efficiency. The reflective layer can further serve to reflect light back in a forward direction that would otherwise be lost through reflection from an external protection film.

Referring now to FIG. 4, according to another embodiment, an LED package 200″ may include a transparent polymer substrate 210, an LED 220, and a polarizing layer 250. As shown in FIG. 5, the LED 220 may be flip-chip bonded to one surface of the transparent polymer substrate 210. The polarizing layer 250 may be disposed on a surface of the transparent polymer substrate 210 opposite the LED 220.

The polarizing layer 250 may, for instance, include a prism having a semicircular cross section as shown in FIG. 4. The prism may, however, have a cross section that is triangular or any other desired shape. The polarizing layer may increase the luminous efficiency by preventing reduction in a degree of concentration caused by light diffusion and by preventing interruption of light being transferred.

Since the polymer substrate 210 is transparent, light generated from the LED 220 may be transmitted through the transparent polymer substrate 210 without being absorbed. The polarizing layer 250 may include a single polarizing plate as shown in FIG. 5, or may include both a vertical polarizing plate and a horizontal polarizing plate, and/or may include a polarizing plate having any desired predetermined angle. The polarizing layer 250 may therefore prevent a reduction in the luminous efficiency caused by diffusion of light and the like.

Referring to FIG. 5, the LED package 200 may include a transparent substrate 210, an LED 220, and both a polarizing layer 250 and a reflective layer 240. As shown in FIG. 5, after the LED 220 is flip-chip bonded to one surface of the transparent substrate 210, the polarizing layer 250 may be disposed on an opposite surface of the transparent substrate 210 with the reflective layer 240 disposed on the polarizing layer 250. By including both the reflective layer 240 and the polarizing layer 250, the luminous efficiency can be further increased. More specifically, the reflective layer 240 and the polarizing layer 250 may be disposed on a surface of the transparent substrate 210, opposite to the surface on which the LED 220 is disposed. The polarizing layer 250 may include a horizontal polarizing layer or horizontal polarizing plate or a vertical polarizing layer or vertical polarizing plate (or both) as desired. The polarizing layer or plate 250 may include a plurality of prisms each having a triangular or semicircular cross section. In particular, when the prism has a semicircular cross section, the polarizing layer 250 may also function as a diffusion layer.

The polarizing layer 250 and the reflective layer 240 may be disposed over the entire opposing surface of the transparent substrate, or they may be formed to be larger than a surface area of the LED 220, yet smaller than the entire opposing surface area of the transparent substrate 210.

When the reflective layer 240 or the polarizing layer 250 is disposed over the entire opposing surface of the transparent substrate 210, the reflection and/or polarization effects are expected to be optimal. However, using such a configuration may not be cost-effective in terms of the unit cost of production. When the reflective layer and/or the polarizing layer are smaller than the surface area of the LED, a portion of the light generated from the LED may not be reflected or polarized. Therefore, the reflective layer and the polarizing layer are preferably larger than the surface area of the LED. However, since it may be uneconomical to form the reflective layer or the polarizing layer over the entire opposing surface of the substrate, the reflective layer and the polarizing layer may be larger in size than the surface area of the LED, yet smaller than the entire opposing surface area of the transparent substrate.

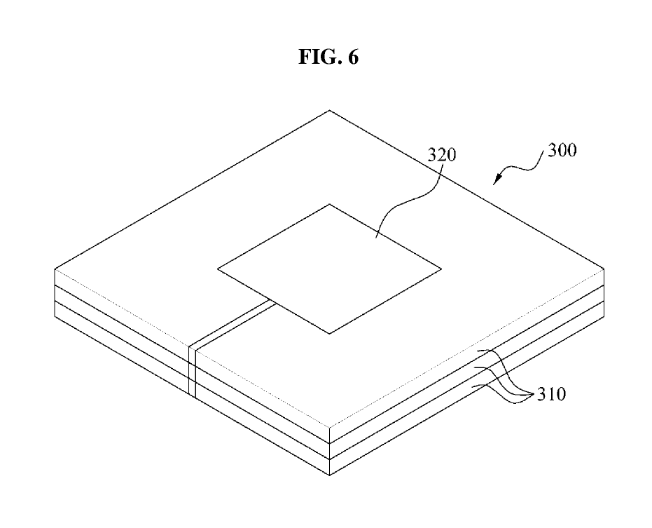

FIG. 6 is a schematic diagram of a stacked structure 300 of LED packages, according to yet another embodiment of the present inventive concepts. Referring to FIG. 6, a stacked structure 300 according embodiments of the present inventive concepts can include at least two aforementioned LED packages being stacked together. The stacked structure may be useful, for instance, when a high intensity LED is necessary. Where the LED package is formed by flip-chip bonding or direct vapor-deposition, stacking of the LED packages may be easily achieved with a minimal height.

As shown in FIG. 6, the LED packages can be stacked in one direction, that is, such that surfaces of transparent substrates 310 on which LEDs 320 are disposed are arranged facing the same direction (i.e., unidirectionally). When the LED packages are stacked unidirectionally, since light is collected in one direction, for example in a forward direction, light of higher radiation intensity may be emitted.

The unidirectional stacked body may implement various colored LEDs to induce color mixing. When white light and red light are mixed, for example, a color rendering index (CRI) may be increased.

The stacked structure of the LED packages may also include a reflective layer or a polarizing layer. The reflective layer may, for example, be disposed on a lower surface of a transparent substrate of a lowermost LED package of the unidirectional stacked structure, that is, on a surface of the substrate of the lowermost LED package, opposite to a surface on which the lowermost LED is formed.

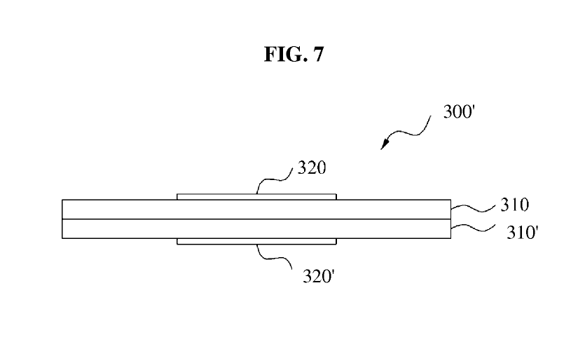

Alternatively, the LED packages may be stacked symmetrically, that is, in opposite directions with respect to each other (i.e., bidirectionally). FIG. 7 illustrates a stacked structure of LED packages, according to another embodiment of the present inventive concepts, in which the stacked structure is a bidirectional LED package stacked structure.

Referring to FIG. 7, the transparent substrates of the LED packages 310, 310′ can be bonded together such that the LEDs 320, 320′ are arranged symmetrically with respect to the transparent substrates 310, 310′. That is, LEDs 320, 320′ of the LED packages can be directed opposite to each other. The bidirectional LED package stacked structure 300′ can be configured to emit light in every direction, not just unidirectionally or bidirectionally.

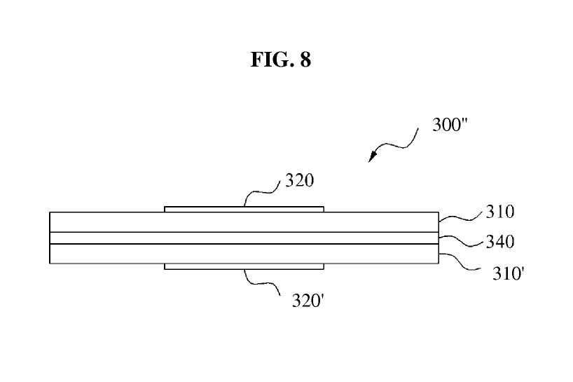

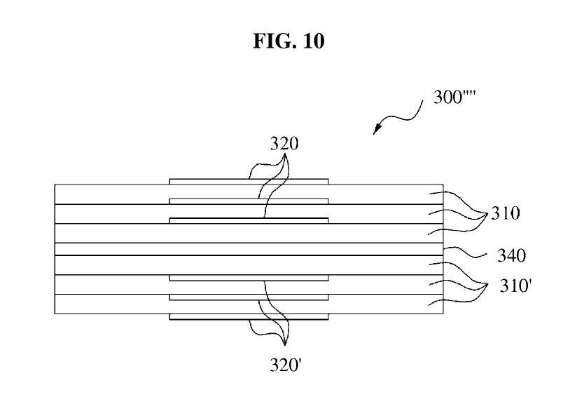

The bidirectional stacked structure may be utilized when bidirectional light emission is desired. As shown in FIG. 7, in the bidirectional stacked structure, two LED packages may be arranged with the LEDs 320, 320′ facing opposite directions, such that the opposing surfaces of the substrates 310, 310′ of the respective LED packages face and/or contact each other. In an alternative embodiment, one or more additional LED packages may be stacked unidirectionally on each of the two LED packages, thereby providing a bidirectional stacked body of LED packages (see FIG. 10). The bidirectional stacked body may also include a reflective layer and/or a polarizing layer (see FIGS. 8 through 10). The reflective layer 340 may be disposed between the substrates 310 of the LED packages (see FIG. 8). In this case, each of the opposing surfaces of the reflective layer can provide reflective surfaces so that light can be reflected back in the direction of each of the LEDs 320.

FIG. 8 illustrates a stacked structure of LED packages 300″, according to a still further embodiment of the present inventive concepts, in which a bidirectional LED stacked package structure includes a reflective layer 340. Referring to FIG. 8, a first LED 320 can be flip-chip bonded to one surface of a transparent substrate 310, thereby forming a first LED package. A second LED 320′ can be disposed on a surface of another transparent substrate 310′, thereby forming a second LED package. A reflective layer 340 can be disposed on a surface of the transparent substrate 310 of the first LED package, opposite the first LED 320. The first LED package and the second LED package can then be bonded together such that a rear surface of the transparent substrate 310′ of the second LED package (i.e., the surface opposite that on which the second LED 320 is disposed), contacts the reflective layer 340 that is disposed on the first LED package. In this manner, the LEDs 320, 320′ of the two LED packages are configured to face opposite directions.

The reflective layer 340 can be configured to be capable of bidirectional reflection. The bidirectional LED stacked package structure of this embodiment can thereby be configured to emit light bidirectionally with an increased luminous efficiency over embodiments without the reflective layer.

The reflective layer may be arranged in a stacked structure in which materials having a high refractive index and materials having a low refractive index are alternately stacked. Materials having a high refractive index may include, for example, tantalum pentoxide (Ta₂O₅) (having a refractive index of about 2.2), tin oxide (TiO₂) (having a refractive index of about 2.41), Niobium pentoxide (Nb₂O₅) (having a refractive index of about 2.41), and the like. Materials having a low refractive index may include, for example, silicon oxide (SiO₂) (having a refractive index of about 1.46), and the like. An uppermost layer to be arranged in contact with the atmosphere, a phosphor layer, or the LED chip may include one or more materials having a low refractive index.

A polarizing layer may also be disposed between respective neighboring LED packages, irrespective of whether a unidirectional or bidirectional stacked body structure is implemented.

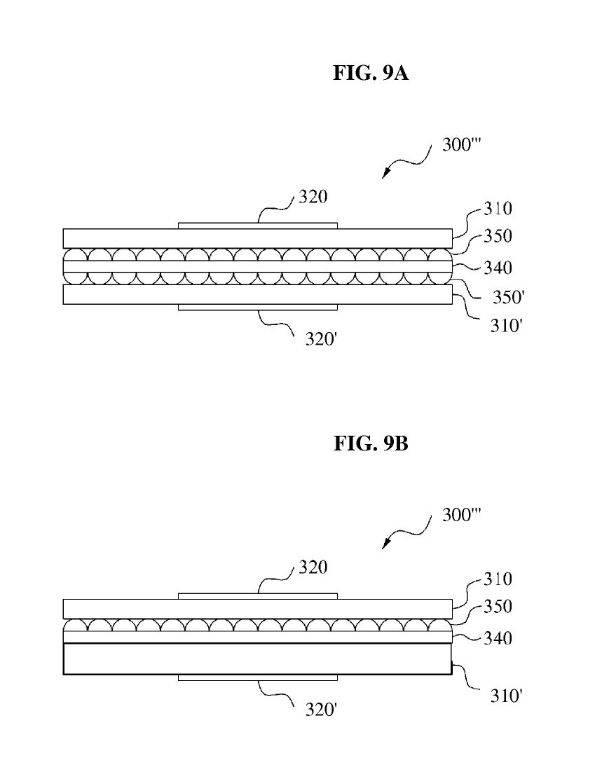

FIGS. 9A and 9B illustrate stacked LED package structures 300′″ according to yet other embodiments of the present inventive principles. As illustrated, the stacked LED package structure may be a bidirectional LED package stacked structure including both a reflective layer 340 and one or more polarizing layers 350, 350′.

Referring to FIG. 9A, an LED 320 can be flip-chip bonded to one surface of a transparent substrate 310, thereby forming a first LED package. Another LED 320′ can be formed in a similar manner on a second transparent substrate 310′, thereby forming the second LED package. A polarizing layer 350 can be formed on a surface of the transparent substrate opposite the first LED 320. After the polarizing layer 350 is formed on an opposite surface of the transparent substrate 310 of the first LED package, the reflective layer 340 can be formed and then another polarizing layer 350′ can be formed thereon. The second transparent substrate 310 for constructing a second LED package can then be prepared and attached to the second polarizing layer 350′ on a surface opposite the second LED 320′.

The bidirectional LED package stacked structure shown in FIG. 9A may, however, be fabricated by forming the first LED package and the second LED package, forming the polarizing layers 350, 350′ on each transparent substrate of both LED packages, and bonding a reflective layer 340 capable of bidirectional reflection between the polarizing layers. The embodiment shown in FIG. 9B is similar to that shown in FIG. 9a, but lacks one of the polarizing layers 350′. Of course, as explained previously, the polarizing layers 350, 350′ can be configured as polarizers and/or diffusers, having a semicircular or triangular cross-sectional shape pattern, to emit vertical or horizontally arranged light wavelengths (or wavelengths of any other desired orientation), or in any combination of the above or other desired features.

The LED package stacked structure of these embodiments may emit light bidirectionally with an increased luminous efficiency being provided by the reflective layer 340 and the polarizing layer(s) 350, 350′.

FIG. 10 is a sectional view of a stacked structure of LED packages 300″″, according to a still further embodiment of the present inventive concepts. As mentioned previously, the stacked structure shown in FIG. 10 provides a bidirectional LED package stacked structure which includes a reflective layer 340 and a plurality of LED packages 310, 310′ stacked on each of the opposing LED packages.

Referring to FIG. 10, a plurality of LED packages may be stacked respectively on the first LED package and the second LED package of the bidirectional LED package stacked structure shown in FIG. 8. Each of the plurality of LED packages may be stacked in the same direction as the respective first or second LED package. That is, each respective stack may be arranged unidirectionally with regard to its respective base package, with the overall package 300″″ providing a bidirectional stacked structure.

The LED package stacked structure of this embodiment may thus be configured to bidirectionally emit light having a high radiation intensity, and further having an increased luminous efficiency by virtue of the reflective layer 340. In addition, as with the other embodiments, one or more polarizing layers may also be included to further increase luminous efficiency.

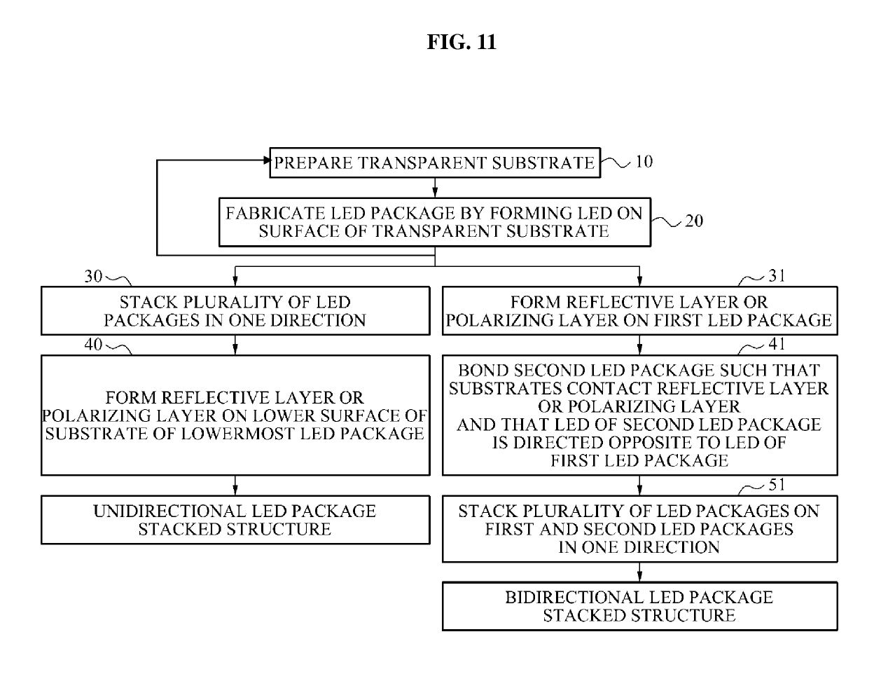

FIG. 11 is a flow chart illustrating LED package fabrication methods according to another aspect of the present inventive concepts. More particularly, FIG. 11 illustrates fabrication processes for both a unidirectional stacked structure and a bidirectional stacked structure of LED packages. Referring to FIG. 11, various manufacturing processes will now be described.

As shown in FIG. 11, for either of these manufacturing processes, a transparent substrate is first prepared in operation 10. An LED is then disposed on one surface of the transparent substrate in operation 20, thus forming an LED package for fabricating the stacked structure. Any desired number of LED packages can be prepared by repeating these two operations. Following preparation of the desired number of LED packages, a stacking order, as well as an orientation and location of a reflective layer may vary depending on whether the desired stacked structure is unidirectional or bidirectional.

When a unidirectional stacked structure is being fabricated, the LED packages are stacked in a single direction in operation 30. In operation 40, a reflective layer and/or a polarizing layer may be disposed on a lower surface of a transparent substrate of a lowermost LED package. That is, the reflective and/or polarizing layer is arranged on a surface of the lowermost transparent substrate opposite to a surface on which the lowermost LED is formed. Alternatively, before stacking the LED packages, the reflective layer and/or the polarizing layer may first be formed first on a lower surface of an LED package to be stacked at a lowermost position. The remainder of the LED package can then be stacked on an opposite surface (i.e., the surface on which the LED is formed) of the lowermost LED package.

When a bidirectional stacked structure is to be fabricated, a reflective layer and/or one or more polarizing layers may be disposed on a surface of a first LED package, opposite to a surface on which an LED is formed, in operation 31. In operation 41, a second LED package may be bonded to the first LED package such that a surface of a transparent substrate of the second LED package, opposite to a surface on which an LED is formed, contacts the reflective layer and/or the polarizing layer. Additional LED packages can further be disposed on upper surfaces (i.e., the surfaces on which the LEDs are respectively disposed) of the first LED package and the second LED package, in operation 51. Accordingly, a bidirectional stacked structure of LED packages can be provided.

According to another aspect of the present inventive concepts, a method of fabricating an LED package may include forming an LED on one surface of a transparent substrate. Forming the LED may be performed by mounting a flip chip on the transparent substrate or vapor-depositing the LED directly on the transparent substrate. The fabrication method may further include forming either or both of a reflective layer and a polarizing layer.

The reflective layer may be configured in a multilayer structure using two or more materials between which a difference of refractive indices is great. That is, the multilayer structure may be constructed by repeatedly forming a thin film of a material having a high refractive on the transparent substrate and forming a thin film of a material having a low refractive index on the thin film of the material having a high refractive index. An uppermost layer to be in contact with the atmosphere, a phosphor layer, or the LED chip may be formed from one or more materials having a low refractive index. Formation of each layer is not specifically limited.

When forming the LED package using flip chip mounting or vapor deposition on the transparent substrate, wire frames are unnecessary. Thus, the omission of materials and steps may reduce the unit cost of production.

Although a few exemplary embodiments of the present inventive concepts have been shown and described, the present inventive concepts are not limited to the described exemplary embodiments. Instead, it should be appreciated by those skilled in the art that changes may be made to these exemplary embodiments without departing from the principles and spirit of the inventive concepts, the scope of which is defined by the claims and their equivalents.

What is claimed is:

1. A light emitting diode (LED) package comprising:
a transparent substrate including at least one material selected from a group consisting of: indium tin oxide (ITO), a carbon nanotube (CNT), tin oxide (SnO₂), zinc oxide (ZnO), glass, a conductive polymer, poly(3,4-ethylene dioxythiophene) (PEDOT), grid electrode film (GEF), coating or mesh containing a conductive material, a compound of glass fibers and organic materials, and carbon graphene; and
an LED disposed on one surface of the transparent substrate.

2. The LED package of claim 1, wherein the transparent substrate is a flexible substrate.

3. The LED package of claim 1, wherein the LED is flip-chip bonded to or vapor-deposited on the transparent substrate.

4. The LED package of claim 1, further comprising a reflective layer disposed on the transparent substrate.

5. The LED package of claim 4, wherein the reflective layer is arranged on an opposing surface of the transparent substrate, said opposing surface located opposite the surface on which the LED is disposed.

6. The LED package of claim 5, wherein the reflective layer covers an area of the opposing surface that is larger than an area covered by the LED but smaller than a total area of the opposing surface.

7. The LED package of claim 6, wherein the reflective layer covers all or substantially all of the opposing surface.

8. The LED package of claim 1, further comprising a polarizing layer disposed on the transparent substrate.

9. The LED package of claim 8, further comprising a reflective layer disposed on the polarizing layer.

10. The LED package of claim 1, further comprising at least two LED packages, wherein the at least two LED packages are stacked.

11. The LED package of claim 10, further comprising a reflective layer disposed between the at least two LED packages being stacked.

12. The LED package of claim 10, further comprising a polarizing layer disposed between the at least two LED packages being stacked.

13. A method of fabricating a light emitting diode (LED) package, the fabrication method comprising:
forming an LED on one surface of a transparent substrate,
wherein forming the LED is performed by mounting a flip-chip on the transparent substrate or vapor-depositing the LED directly on the transparent substrate.

14. The method according to claim 13, further comprising forming a polarizing layer on the transparent substrate.

15. The method according to claim 14, wherein the polarizing layer is formed on a surface of the transparent substrate opposite a surface of the transparent substrate on which the LED is formed.

16. The method according to claim 13, further comprising forming a reflective layer on the LED package.

17. The method according to claim 16, wherein the reflective layer is formed on a surface of the transparent substrate opposite a surface of the transparent substrate on which the LED is formed.

18. The method according to claim 15, further comprising forming a reflective layer on the LED package.

19. The method according to claim 18, wherein the reflective layer is formed on the polarizing layer.

20. A light emitting diode (LED) package comprising:
a transparent substrate;
an LED formed on one surface of the transparent substrate; and
a reflective layer or a polarizing layer formed on an opposing surface of the transparent substrate, said opposing surface being located opposite the surface on which the LED is formed.
